(19) United States
(12) Patent Application Publication
(10) Pub. No.: US 2009/0294853 A1
(43) Pub. Date: Dec. 3, 2009

(54) THIN FILM TRANSISTOR HAVING A COMMON CHANNEL AND SELECTABLE DOPING CONFIGURATION

(76) Inventors: Germain L. Fenger, West Henrietta, NY (US); Karl D. Hirschman, Henrietta, NY (US); Robert Manley, Rochester, NY (US); Carlo Anthony Kosik Williams, Painted Post, NY (US)

Correspondence Address: CORNING INCORPORATED, SP-TI-3-1, CORNING, NY, 14831, US

(21) Appl. No.: 12/474,731

(22) Filed: May 29, 2009

Related U.S. Application Data
(60) Provisional application No. 61/130,443, filed on May 30, 2008.

(51) Int. Cl. H01L 29/786; H01L 21/336

(52) U.S. Cl. 257/347; 438/149; 257/E29.273; 257/E21.411

(57) ABSTRACT

Methods and apparatus for producing a thin film transistor (TFT) result in: a semiconductor layer; a channel region formed on or in the semiconductor layer and having first and second opposing ends, and having third and fourth opposing ends transverse to the first and second ends; an n-type source structure disposed on or in the semiconductor layer adjacent to the first end of the channel; an n-type drain structure disposed on or in the semiconductor layer adjacent to the second end of the channel; a p-type source structure disposed on or in the semiconductor layer adjacent to the third end of the channel; a p-type drain structure disposed on or in the semiconductor layer adjacent to the fourth end of the channel; and a gate structure disposed over the channel region.

### PRIORITY

This application claims priority to U.S. Patent Application No. 61/130,443, filed May 30, 2008, titled “Thin Film Transistor Having A Common Channel and Selectable Doping Configuration”.

### BACKGROUND

The present invention relates to the manufacture of thin film transistors (TFTs), particularly TFTs in which the doping configuration (e.g., p-type or n-type) is selectable.

TFTs are useful devices in many areas of technology, such as electronic applications, including OLEDs, liquid crystal displays (LCDs), photovoltaic devices, integrated circuits, etc.

TFTs may be fabricated using a variety of architectures depending on the type of substrate technology employed, the complexity of the fabrication process, and the desired function and characteristics of the TFT. In the flat panel display industry, TFTs are used for several purposes, including for use as the discrete transistors for switching each pixel of a liquid crystal display (LCD), or for the discrete transistors used to drive the respective pixels of an organic light-emitting diode (OLED) display. There are, of course, many other uses of TFTs in display technologies, including the circuitry related to the discrete pixel circuitry, such as the array control circuitry, driving circuitry, and test circuitry, much of which may be disposed at the periphery of the pixel display area. The pixel display circuitry and the peripheral circuitry may be implemented using so-called p-type or n-type TFTs. An n-type TFT includes respective source and drain structures formed of semiconductor material doped with atoms with more valence electrons then the semiconductor; therefore increasing the number of carrier electrons. A p-type TFT includes respective source and drain structures formed of semiconductor material doped with atoms with fewer valence electrons then the semiconductor; resulting in positive “hole” carriers.

The specific TFT architecture (whether of the n-type, p-type, or other physical characteristics) may be uniquely designed in order to achieve desirable circuit performance. Even on a given display substrate (or other device, integrated circuit, etc.), it may be desirable to use some n-type TFTs and some p-type TFTs, depending on the specific job the TFT is designed to carry out. The state of the art dictates that the type of TFT, either p-type or n-type is established and fixed during the doping phase of the TFT fabrication process—and cannot change thereafter.

The prior art includes some efforts to provide flexibility in the fabrication of TFTs, such as the development of the so-called common channel (or alternatively called common body or cross channel). The common channel TFT includes multiple transistors sharing the same channel. In one example disclosed in U.S. Pat. No. 5,508,548, two N-channel MOSFETS are implemented such that a channel is common between them. This patent describes that higher integrated circuit density is achievable. Another publication, M. K. Erhardt, et al., “Low Temperature Fabrication of Si Thin-film Transistor Microstructures by Soft Lithographic Patterning on Curved Planar Substrates,” Chem. Mater, Vol. 12, p. 3306 (2000), describes that the common channel TFT may provide a means of fabricating test structures. In another example, U.S. Pat. No. 5,955,765 discloses a TFT having multiple gates coupled to a single channel as a means for achieving lower leakage current. Again, however, these state of the art TFTs dictate that the type of TFT, either p-type or n-type is established and fixed during the doping phase of the TFT fabrication process—and cannot change.

Given that design flexibility is desirable in the technologies in which TFTs are employed, particularly in the display field, there would be an advantage to having a flexible biasing scheme in which the type of TFT (n-type or p-type) could be established after the doping phase of the fabrication process (for example, at the back-end of the of the fabrication process).

### SUMMARY

In accordance with one or more embodiments, a TFT includes a common channel structure that can be biased to function either as an n-type or as a p-type TFT. The channel region of the TFT has a pair of n-type source/drain regions as well as a pair of p-type source/drain regions. At the processing back-end (i.e., after the device fabrication process has been carried out), the device can be biased (the electrical connections to the device) to function either as an n-type or as a p-type device. The advantages of this configurable TFT include access to a wider variety of device performance attributes, such as: (i) higher or lower conduction current from the n-type and the p-type TFT, respectively; (ii) higher or lower transconductance from the n-type and the p-type device, respectively; and/or (iii) higher or lower field effect carrier mobility from the n-type or p-type device, respectively. Another advantage of the configurable TFT described above is greater circuit design capability. For example, the common channel TFT structure provides an added level of flexibility in implementing logic gates for either field programmable gate arrays (FPGAs) or programmable logic arrays (PLAs). The configurable TFT can also be used as a powerful metrology for extracting device physics phenomena of both carrier type dynamics within the same channel region. This is very useful for device process monitoring as greater detailed information can be obtained about the electrical properties of the silicon film, as well interface states (silicon-glass and silicon-gate dielectric interfaces).

In accordance with one or more embodiments of the present invention, methods and apparatus of forming a TFT, result in: a semiconductor layer; a channel region formed on or in the semiconductor layer and having first and second opposing ends, and having third and fourth opposing ends transverse to the first and second ends; an n-type source structure disposed on or in the semiconductor layer adjacent to the first end of the channel; an n-type drain structure disposed on or in the semiconductor layer adjacent to the second end of the channel; a p-type source structure disposed on or in the semiconductor layer adjacent to the third end of the channel; a p-type drain structure disposed on or in the semiconductor layer adjacent to the fourth end of the channel; and a gate structure disposed over the channel region.

The application of bias voltages to the gate structure, the n-type source structure, and the n-type drain structure, while leaving the p-type source structure and the p-type drain structure floating, causes the thin film transistor to operate as an n-type field effect transistor. The application of bias voltages to the gate structure, the p-type source structure, and the p-type drain structure, while leaving the n-type source structure and the n-type drain structure floating, causes the thin film transistor to operate as a p-type field effect transistor.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, there are shown in the drawings forms that are presently preferred, it being understood, however, that the invention is not limited to the precise arrangements and instrumentalities shown.

FIG. 1 is a top schematic view of an optical micrograph of a TFT in accordance with one or more aspects of the present invention;

FIG. 2 is a cross-sectional, schematic view of the TFT of FIG. 1 taken through line 2-2;

FIG. 3 is a cross-sectional, schematic view of the TFT of FIG. 1 taken through line 3-3;

FIG. 4 is a graph illustrating the relationship between the drain-to-source current as a function of the gate-to-source voltage of the TFT of FIG. 1 (saturation and linear mode), first operating as an n-type and then operating as a p-type; and

FIG. 5 is a cross-sectional, schematic view of the TFT of FIG. 1 when formed in a semiconductor on insulator substrate configuration.

### DETAILED DESCRIPTION

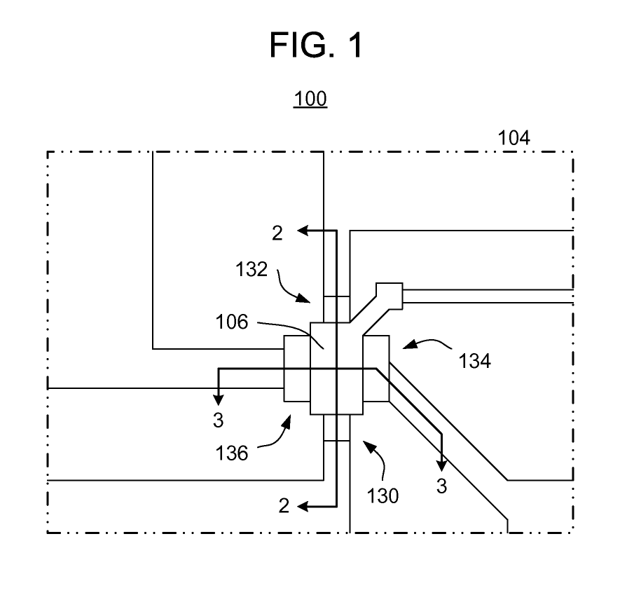

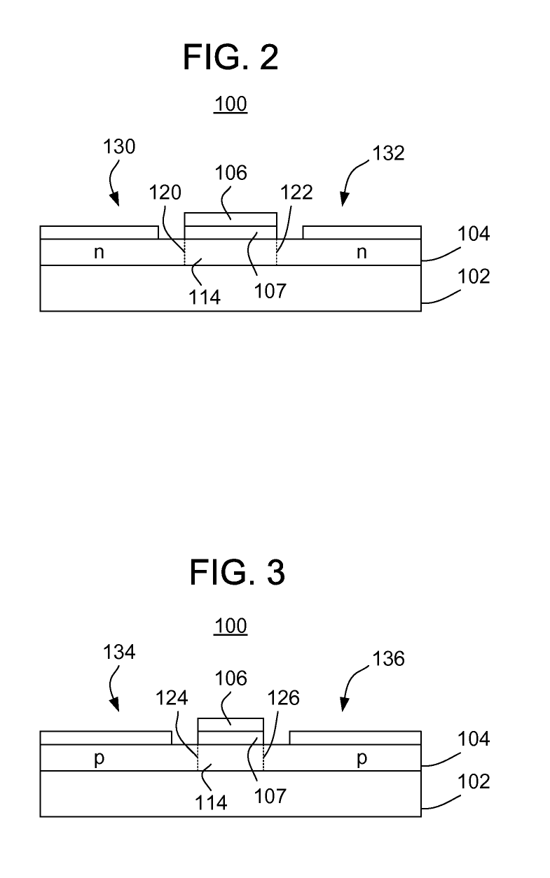

With reference to the drawings, wherein like numerals indicate like elements, there is shown in FIG. 1 a top schematic of a TFT 100 in accordance with one or more aspects of the present invention. FIG. 2 is a cross-sectional, schematic view of the TFT 100 taken through line 2-2, while FIG. 3 is a cross-sectional, schematic view of the TFT 100 taken through line 3-3. The TFT 100 has application for use in displays, such as LCD, OLED displays, or other technologies.

The TFT 100 includes a substrate 102, and a semiconductor layer 104. The substrate 102 may be any of the known substrate materials, such as semiconductor materials, insulators, etc. Disposed on the semiconductor layer 104 of the TFT 100 are a gate contact (or simply “gate”) 106, and a number of source and drain regions. The gate 106 is disposed over an oxide layer 107, which is thus located between the gate 106 and the semiconductor layer 104. A region of the semiconductor layer 104 under the gate oxide 107 is a channel 114 of the TFT 100. The channel 114, formed on or in the semiconductor layer 104, includes first and second opposing ends (channel junctions) 120, 122, and third and fourth opposing ends 124, 126, transverse to the first and second ends 120, 122.

Unlike conventional field effect transistor architectures, which are generally three-terminal devices (gate terminal, drain terminal, and source terminal, with an optional fourth terminal for the bulk semiconductor), the TFT 100 illustrated in FIGS. 1-3 is a five terminal device (with an optional sixth terminal for the bulk semiconductor, not shown). Where a conventional TFT would include one source region/contact and one drain region/contact, the TFT 100 of this embodiment includes multiple source region/contacts and multiple drain region/contacts.

More particularly, the TFT 100 includes an n-type source structure 130 disposed on or in the semiconductor layer 104 adjacent to the first end 120 of the channel 114. An n-type drain structure 132 is disposed on or in the semiconductor layer 104 adjacent to the opposing second end 122 of the channel 114. As best seen in FIG. 2, the above structure results in an n-type field effect transistor, which is operational by providing appropriate bias voltages as is known in the art. Notably, however, the TFT 100 also includes a p-type source structure 134 disposed on or in the semiconductor layer 104 adjacent to the third end 124 of the channel 114, and a p-type drain structure 136 disposed on or in the semiconductor layer 104 adjacent to the opposing fourth end 136 of the channel 114. As best seen in FIG. 3, the above structure results in a p-type field effect transistor, which is operational by providing appropriate bias voltages.

The TFT 100 structure described above may be fabricated by modifying known procedures to achieve the multiple source/drain regions. For example, the semiconductor layer 104 may be subject to patterned oxide and metal deposition procedures (e.g., etching techniques) and doping using ion shower techniques (and or any of the other known techniques). Finally, inter-layers, contact holes, and metal contacts may be disposed using known fabrication techniques to produce the TFT 100. The above fabrication procedures are adapted to result in the respective pairs of n-type and p-type source/drain regions 130, 132 and 134, 136, respectively.

While the TFT 100 is operative in either an n-type or a p-type mode, it may only be configured in one mode at a time—simultaneous operation in both modes is not possible. For operation in the n-type mode, application of bias voltages to the gate 106, the n-type source 130, and the n-type drain 134, while leaving the p-type source 134 and the p-type drain 136 at high impedance state, causes the TFT 100 to operate as an n-type field effect transistor. For operation in the p-type mode, application of bias voltages to the gate 106, the p-type source 134, and the p-type drain 136, while leaving the n-type source 130 and the n-type drain 132 floating, causes the TFT 100 to operate as a p-type field effect transistor. Advantageously, the mode of the TFT 100 may be selected by changing the bias configuration at the back end of the fabrication process.

While those skilled in the art will appreciate that the structures illustrated and described thus far are simplified, it is understood that many of the design nuances of discrete transistor design are available for use with the TFT 100—such details have not been shown and described herein for the purposes of brevity and clarity. One such optional design nuance is illustrated in FIGS. 1-3, whereby the channel 114 of the TFT 100 includes a dimension between the first and second ends 120, 122 thereof that is larger than a dimension between the third and fourth ends 124, 126 thereof. As is known in the art, the magnitude of the source-to-drain current is directly proportional to the product of the field effect carrier mobility and the ratio of the channel width to length. Also known in the art is that the field effect carrier mobility of the n-type TFT can be nominally 2 to 3 times higher than that of the p-type TFT. Since it is desirable in many applications to have balanced source-to-drain current magnitude for both the n-type and p-type TFT, the channel dimensions of TFTs 100 can be designed to achieve the desired conduction current magnitude for the n-type and the p-type TFTs. In this particular embodiment, the dimensions of the channel 114 are such that the p-type and n-type mode of operation employed a channel width/length ratio that allowed for a balanced source-to-drain current.

The TFT 100 may be used to implement circuits for a variety of functionality. These circuits can include logic gates such as AND, OR, NAND, NOR etc. Such circuit logic gates can be used to form programmable logic arrays and/or field programmable logic arrays that allows for rapid in-house circuit design where the circuits and its functionality are integrated directly on the display periphery. Additionally, the TFT 100 is inherently a unique test structure that can be included on a display periphery for back panel test and verification. By analyzing the current versus voltage characteristics of the n-type and the p-type TFT operation for the same channel, more detailed information can be extracted about the device fabrication process, which can allow for improved process optimization and improvements.

In one or more embodiments, the semiconductor material of the layer 104 may be in the form of a substantially single-crystal material on the order of about 10-200 nm thick. The term “substantially” is used in describing the layer 104 to take account of the fact that semiconductor materials normally contain at least some internal or surface defects either inherently or purposely added, such as lattice defects or a few grain boundaries. The term substantially also reflects the fact that certain dopants may distort or otherwise affect the crystal structure of the semiconductor material. For the purposes of discussion, it is assumed that the semiconductor layer 104 is formed from silicon. It is understood, however, that the semiconductor material may be a silicon-based semiconductor or any other type of semiconductor, such as the III-V (i.e. GaAs, GaP, InP, etc.), the IV-IV (i.e. SiGe, SiC), the elemental (i.e. Ge), or the II-VI (i.e. ZnO, ZnTe, etc) classes of semiconductors.

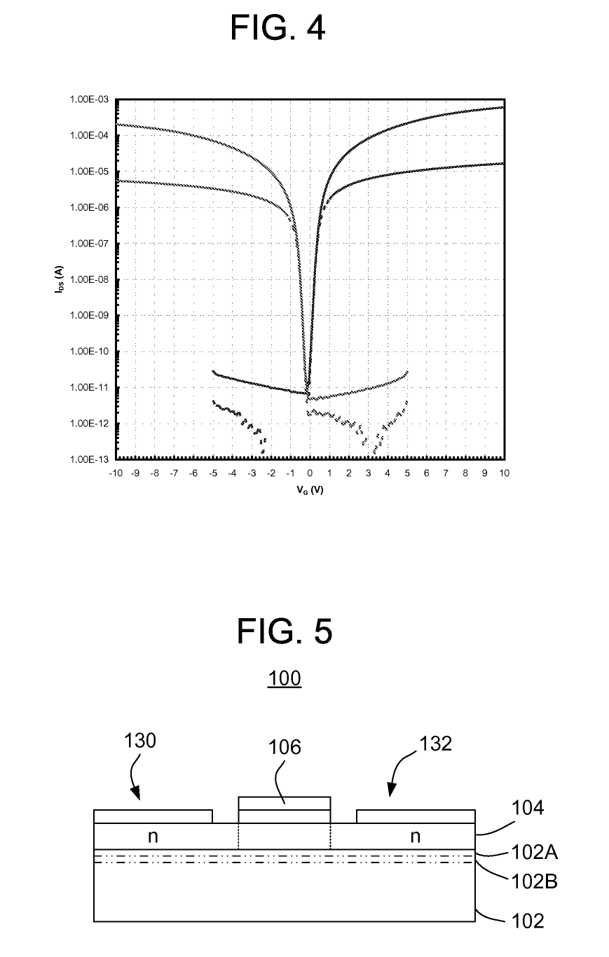

A TFT 100 was fabricated using the above-described structure and materials. Some performance characteristics are illustrated in FIG. 4, which is a graph illustrating the relationship between the drain-to-source current as a function of the gate-to-source voltage of the TFT 100 (saturation and linear mode). The operating characteristics in the n-type mode are graphed to the right of zero gate-to-source voltage, while the operating characteristics in the p-type mode are graphed to the left of zero gate-to-source voltage. Qualitatively, the illustrated I-V characteristics are similar to discrete n-type and p-type FET devices. The parameters of carrier mobility, sub-threshold swing (SS), and threshold voltage (TV) for the TFT 100 are shown in Table 1 below, which are also similar to those discrete n-type and p-type FET devices.

| | Mobility | SS | |
|---|---|---|---|
| Type | cm²/Vs | mV/decade | Threshold |
| N | >400 | ~80 | +0.35 V |
| P | >220 | ~90 | −0.61 V |

FIG. 5 is a cross-sectional, schematic view of the TFT 100 of FIG. 1 when formed in a semiconductor on insulator substrate configuration. The substrate 102 is formed of a glass or glass ceramic material and the semiconductor layer 104 is bonded to the substrate 102, preferably by way of electrolysis.

The glass substrate 102 may be formed from an oxide glass or an oxide glass-ceramic in the range of about 0.1 mm to about 10 mm, such as in the range of about 0.5 mm to about 3 mm. By way of example, the glass substrate 102 may be formed from glass substrates containing alkaline-earth ions and may be silica-based, such as, substrates made of CORNING INCORPORATED GLASS COMPOSITION NO. 1737 or CORNING INCORPORATED GLASS COMPOSITION NO. EAGLE 2000®. These glass materials have particular use in, for example, the production of displays. The glass or glass-ceramic substrate 102 may be designed to match a coefficient of thermal expansion (CTE) of one or more semiconductor materials (e.g., silicon, germanium, etc.) of the layer 104 that are bonded together. The CTE match ensures desirable mechanical properties during heating cycles of the deposition process.

The single crystal semiconductor layer 104 may be bonded to the glass substrate 102 using any of the existing techniques. Among the suitable techniques is bonding using an electrolysis process. A suitable electrolysis bonding process is described in U.S. Pat. No. 7,176,528, the entire disclosure of which is hereby incorporated by reference. Portions of this process are discussed below. In the bonding process, a semiconductor donor wafer (e.g., a single crystal silicon wafer) is subject to ion implantation, such as hydrogen and/or helium ion implantation, to create a zone of weakness below a bonding surface of the donor wafer. The glass substrate 102 and the bonding surface of the donor semiconductor wafer are brought into direct or indirect contact and are heated under a differential temperature gradient. Mechanical pressure is applied to the intermediate assembly (e.g., about 1 to about 50 psi.) and the structure is taken to a temperature within about ±150 degrees C. of the strain point of the glass substrate 102. A voltage is applied with the donor semiconductor wafer at a positive potential and the glass substrate 102 a negative potential. The intermediate assembly is held under the above conditions for some time (e.g., approximately 1 hour or less), the voltage is removed and the intermediate assembly is allowed to cool to room temperature.

As some point during the above process, the donor semiconductor wafer and the glass substrate 102 are separated, to obtain a glass substrate 102 with a relatively thin exfoliation layer of the semiconductor material bonded thereto. The separation of the donor semiconductor wafer from the exfoliation layer that is bonded to the glass substrate 102 is accomplished through application of stress to the zone of weakness within the donor semiconductor wafer, such as by a heating and/or cooling process. It is noted that the characteristics of the heating and/or cooling process may be established as a function of a strain point of the glass substrate 102. Although the invention is not limited by any particular theory of operation, it is believed that glass substrates 102 with relatively low strain points may facilitate separation when the respective temperatures of the donor semiconductor wafer and the glass substrate 102 are falling or have fallen during cooling. Similarly, it is believed that glass substrates 102 with relatively high strain points may facilitate separation when the respective temperatures of the donor semiconductor wafer and the glass substrate 102 are rising or have risen during heating. Separation of the donor semiconductor wafer and the glass substrate 102 may also occur when the respective temperatures thereof are neither substantially rising nor falling (e.g., at some steady state or dwell situation).

The application of the electrolysis bonding process causes alkali or alkaline earth ions in the glass substrate 102 to move away from the semiconductor/glass interface further into the glass substrate 102. More particularly, positive ions of the glass substrate 102, including substantially all modifier positive ions, migrate away from the higher voltage potential of the semiconductor/glass interface, forming: (1) a reduced positive ion concentration layer 102A in the glass substrate 102 adjacent the semiconductor/glass interface; and (2) an enhanced positive ion concentration layer 102B of the glass substrate 102 adjacent the reduced positive ion concentration layer. This accomplishes a number of features: (i) an alkali or alkaline earth ion free interface (or layer) is created in the glass substrate 102; (ii) an alkali or alkaline earth ion enhanced interface (or layer) is created in the glass substrate 102; (iii) an oxide layer is created between the exfoliation layer and the glass substrate 102; and (iv) the glass substrate 102 becomes very reactive and bonds to the exfoliation layer strongly with the application of heat at relatively low temperatures. Additionally, relative degrees to which the modifier positive ions are absent from the reduced positive ion concentration layer in the glass substrate 102, and the modifier positive ions exist in the enhanced positive ion concentration layer are such that substantially no ion re-migration from the glass substrate 102 into the exfoliation layer (and thus into any of the structures later formed thereon of therein).

The cleaved surface of the SOI structure just after exfoliation may exhibit excessive surface roughness, excessive semiconductor layer 104 thickness, and implantation damage of the semiconductor layer 104 (e.g., due to the formation of a damaged semiconductor layer). Post processing is carried out to achieve a desired thickness of the semiconductor layer 104, such as a thickness of about 10-200 nm.

The channel 114, the gate 106, the n-type source structure 130, the n-type drain structure 132, the p-type source structure 134, and the p-type drain structure 136 may be disposed on or in the semiconductor layer 104 using appropriate procedures.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A thin film transistor (TFT), comprising:
a semiconductor layer;
a channel region formed on or in the semiconductor layer and having first and second opposing ends, and having third and fourth opposing ends transverse to the first and second ends;
an n-type source structure disposed on or in the semiconductor layer adjacent to the first end of the channel;
an n-type drain structure disposed on or in the semiconductor layer adjacent to the second end of the channel;
a p-type source structure disposed on or in the semiconductor layer adjacent to the third end of the channel;
a p-type drain structure disposed on or in the semiconductor layer adjacent to the fourth end of the channel; and
a gate structure disposed over the channel region.

2. The thin film transistor of claim 1, wherein application of bias voltages to the gate structure, the n-type source structure, and the n-type drain structure, while leaving the p-type source structure and the p-type drain structure at high impedance, causes the thin film transistor to operate as an n-type field effect transistor.

3. The thin film transistor of claim 1, wherein application of bias voltages to the gate structure, the p-type source structure, and the p-type drain structure, while leaving the n-type source structure and the n-type drain structure at high impedance, causes the thin film transistor to operate as a p-type field effect transistor.

4. The thin film transistor of claim 1, wherein a dimension between the first and second ends of the channel is different than a dimension between the third and fourth ends of the channel.

5. The thin film transistor of claim 4, wherein the dimension between the first and second ends of the channel is larger than the dimension between the third and fourth ends of the channel.

6. The thin film transistor of claim 1, wherein the semiconductor layer is a single crystal semiconductor material.

7. The thin film transistor of claim 6, wherein the semiconductor layer is formed from a material taken from the group consisting of: silicon (Si), germanium-doped silicon (SiGe), silicon carbide (SiC), germanium (Ge), gallium arsenide (GaAs), GaP, and InP.

8. The thin film transistor of claim 1, wherein the semiconductor layer is coupled to a glass or glass ceramic substrate.

9. The thin film transistor of claim 1, wherein:
the semiconductor layer is coupled to a glass or glass ceramic substrate; and
the semiconductor layer is a single crystal semiconductor material.

10. The thin film transistor of claim 9, wherein the glass or glass ceramic substrate includes:
a first layer adjacent to the single crystal semiconductor layer with a reduced positive ion concentration having substantially no modifier positive ions; and
a second layer adjacent to the first layer with an enhanced positive ion concentration of modifier positive ions, including at least one alkaline earth modifier ion from the first layer.

11. The thin film transistor of claim 9, wherein the glass or glass ceramic substrate includes:
a first layer adjacent to the single crystal semiconductor layer with a reduced positive ion concentration having substantially no modifier positive ions;
a second layer adjacent to the first layer with an enhanced positive ion concentration of modifier positive ions; and
relative degrees to which the modifier positive ions are absent from the first layer and the modifier positive ions exist in the second layer are such that substantially no ion re-migration from the glass or glass ceramic substrate into the single crystal semiconductor layer may occur.

12. A method of forming a thin film transistor (TFT), comprising:
forming a channel region on or in a semiconductor layer such that the channel has first and second opposing ends, and has third and fourth opposing ends transverse to the first and second ends;
disposing an n-type source structure on or in the semiconductor layer adjacent to the first end of the channel;
disposing an n-type drain structure on or in the semiconductor layer adjacent to the second end of the channel;
disposing a p-type source structure on or in the semiconductor layer adjacent to the third end of the channel;
disposing a p-type drain structure on or in the semiconductor layer adjacent to the fourth end of the channel; and
disposing a gate structure disposed over the channel region.

13. The method of claim 12, further comprising applying bias voltages to the gate structure, the n-type source structure, and the n-type drain structure, while leaving the p-type source structure and the p-type drain structure at high impedance, such that the thin film transistor operates as an n-type field effect transistor.

14. The method of claim 12, further comprising applying bias voltages to the gate structure, the p-type source structure, and the p-type drain structure, while leaving the n-type source structure and the n-type drain structure at high impedance, such that the thin film transistor operates as a p-type field effect transistor.

15. The method of claim 12, wherein at least one of:
the method further comprises coupling the semiconductor layer to a glass or glass ceramic substrate; and
the semiconductor layer is a single crystal semiconductor material.

16. The method of claim 15, wherein the semiconductor layer is taken from the group consisting of: silicon (Si), germanium-doped silicon (SiGe), silicon carbide (SiC), germanium (Ge), gallium arsenide (GaAs), GaP, InP, ZnO and ZnTe.
